(19) United States
(12) Patent Application Publication
(10) Pub. No.: US 2011/0147908 A1
(43) Pub. Date: Jun. 23, 2011

(54) Module for Use in a Multi Package Assembly and a Method of Making the Module and the Multi Package Assembly

(76) Inventors: Peng Sun, Shen Zhen (CN); Chi Kuen Vincent Leung, Tin Shui Wai (HK); Xun Qing Shi, Tai Wai (HK)

(21) Appl. No.: 12/640,946

(22) Filed: Dec. 17, 2009

(51) Int. Cl. H01L 23/52; H01L 21/60

(52) U.S. Cl. 257/686; 438/109; 257/690; 257/E21.506; 257/E23.141

(57) ABSTRACT

The module comprises a first substrate and at least one chip mounted on the first substrate. A second substrate is mounted to the first substrate and has an opening therein. The opening is lined with the at least one chip. The second substrate is overmolded and the first substrate is electrically connected to the second substrate by at least one first electrical connector. At least one second electrical connector extends from the second substrate through the overmold and has its exposed ends for electrical connection to an external module. The external module may be mounted to the first module in order to form a package on package assembly.

### TECHNICAL FIELD

The present invention relates to package on package (PoP) technology. In particular it relates to a module for use in a multi-package assembly and a method of making the module and a multi-package assembly.

### BACKGROUND OF THE INVENTION

A package on package (PoP) comprises two electronic packages assembled in a vertical stack. It may use a variety of package styles, but fine-pitch ball grid array (FBGA) is the most common.

A typical PoP assembly 1 is shown in FIG. 1. It comprises a first electronic package 5 mounted on top of a second electronic package 10. Typically the top package 5 has a memory device, while the bottom package has a processor.

Due to their compact nature, PoP assemblies are used in many electronic devices. For example in a mobile phone the top package may have a memory device and the bottom package a baseband or applications processor. In a digital camera the top package may have a memory device and the bottom package an image processor. In a handheld computer or game system, the top package may have a memory device and the bottom package an audio or graphics processor.

The top package in FIG. 1 has a substrate 20. Typically the substrate will be a BT core substrate. A pair of chips 30, 31 are mounted to the substrate 20. Wires 16, 18 connect the chips 30, 31 to electrical contacts 11 of the substrate 20. The top package is covered with a molding compound 30 (over molded). This strengthens the assembly and helps to protect the components from damage.

The lower package 10 also comprises a substrate 40 and a chip 50 mounted to the substrate. The chip 50 is connected to electrical contacts 41 of the substrate by wires 45. An overmold 60 covers the chip 50 and a surrounding part of the substrate on which the chip is mounted.

The top package 5 is mounted to the bottom package 10 by solder balls 70. The solder balls 70 space the two packages apart allowing room for the chip 50 of the lower package. The solder balls 70 connect with electrical contacts on the lower side of the substrate 20 and electrical contacts on the upper surface of the substrate 40. This allows electrical signals to be passed between the upper and lower packages.

Solder balls 80 are provided on the lower surface of the substrate 40 of the lower package 10. They connect with electrical contacts (e.g. plates or lands) on the lower surface of the substrate 40. They allow the PoP to communicate with an external module, such as a motherboard.

### SUMMARY OF THE INVENTION

There are certain problems with the PoP shown in FIG. 1. Firstly as electronic devices increase in complexity it is necessary to increase the density of connections, which requires very fine pitch of connectors. This is difficult to achieve.

Secondly, the space between the upper and lower packages is limited. It would be desirable to increase the vertical separation (stand off height) in order to make room for more and larger chips and enable stacking of chips on the lower substrate.

Thirdly, warpage of one or both substrates 20, 40 can deform the connection and solder joints between the upper and lower packages. This is especially the case where one of the substrate warps due to variations in temperature. The response of the different substrates and different components of the PoP to temperature is rarely the same, which exacerbates the problem.

In one aspect of the present invention a (first) module is proposed comprising a first substrate and at least one chip mounted on the first substrate; a second substrate mounted to the first substrate and having an opening in therein; said opening being aligned with said at least one chip on the first substrate; the second substrate being overmolded; the first substrate being electrically connected to the second substrate by at least one first electrical connector; and at least one second electrical connector extending from the second substrate through the overmold and having an exposed end for electrical connection to an external module.

Preferably the module is for use in a multi-package assembly. A “multi-package assembly” is an assembly comprising two electronic packages each of which has a chip mounted to a substrate. The module may be used as the lower package in a PoP. A second (upper) module may be mounted to the first module to form the PoP. The second module may make electrical contact with the exposed end(s) of the second electrical connector(s) in order to enable communication between the two modules or packages.

As the lower module has a second substrate with electrical connectors on either side, the stand off height may be increased. Further, the opening in the second substrate makes room for one or more chips mounted to the first substrate. Overmolded means that molding material covers the second substrate. As the ‘intermediate’ second substrate and the second connectors are overmolded, the assembly is less prone to warpage. Preferably the at least one chip is overmolded. Preferably the first substrate is overmolded. Preferably the overmold extends over the first substrate at least as far as the second substrate; more preferably the whole of the first substrate is overmolded. The assembly is also relatively cheap to manufacture compared to other arrangements which require laser drilling or other complex machinery.

Preferably there are a plurality of first electrical connectors and a plurality of second electrical connectors. For example, there may be four or more first electrical connectors on the underside of the second substrate and four or more second electrical connectors on the top side of the second substrate. Preferably the first and second electrical connectors are metal pillars, e.g. copper pillars. Preferably the first and second electrical connectors are separate pieces (i.e. not integral parts of the same pillar). Metal pillars allow for fine pitch and maintain their shape at high processing temperatures (e.g. 260° C.), compared to solder joints which melt and break down at such temperatures. However, solder joints may be used to join the metal pillars to a substrate above or below (e.g. to the second substrate and to the first substrate or to a substrate of an external module mounted to the first module).

The second substrate may have only a single layer. The single layer is preferably an insulating layer, e.g. made of polymer. Alternatively the second substrate may have plural layers. For example, the second substrate may comprise a core insulator layer and conducting layers on either side of the core layer. There may be insulating layers (e.g. solder resists) outward on either side of the conducting layers.

One or more vias preferably extend through said second substrate. The vias electrically connect the at least one first electrical connector with the at least one second electrical connector. Preferably the via and the first and second electrical connectors which the via connects are three separate pieces.

Each via typically comprises first and second electrically conductive side walls. The first and second side walls are electrically connected to each other by the first electrical connector and said second electrical connector (at either end of the via). The term side walls as used herein includes the situation where the two ‘side walls’ are part of the same wall, e.g. different parts of a circular wall. The via may have an insulating core. Alternatively the via may have metal side walls and a metal core, or an insulating sidewalls and a conducting core.

The at least one first electrical connector and at least one second electrical connector are preferably aligned with each other (on opposite sides of the second substrate).

A second aspect of the present invention provides a multi-package assembly comprising the module of the first aspect of the present invention as the first module and a second module comprising a chip mounted on a third substrate. The second module may be mounted to the first module; preferably it is mounted directly to the overmold of the first module.

The third substrate is preferably mounted to the first module. For example the third substrate may be mounted to the second substrate of the first module via overmold of the second substrate and/or the second electrical connectors.

Preferably the at least one second electrical connector is in electrical contact with a conducting contact of the third substrate. Preferably the at least one second connector is in direct physical contact with the third substrate.

The chip of the second module is preferably mounted to a first side of the third substrate and a second side of the third substrate is preferably mounted to the first module. E.g. the third substrate may be mounted to the second substrate via the overmold of the second substrate and/or the second electrical connectors.

In one arrangement the chip of the first module is a processor and the chip of the second module is a memory chip.

A third aspect of the present invention provides a method of manufacturing a first module (preferably for use in a multi-package assembly), comprising providing a second substrate having at least first electrical connector on a first side thereof and at least one second electrical connector on a second side thereof and one or more openings; mounting the second substrate to a first substrate; mounting one or more chips on the first substrate via the space provided by the opening in the second substrate; (optionally connecting the chip to the substrate with one or more wires); adding molding material to cover the first substrate and the second substrate and the chips, but preferably leaving exposed a surface of the at least one second electrical contact. Alternatively the surface of the at least one second electrical contact may be covered by the molding material and the part of the molding material covering the surface of the at least one second electrical contact may later be removed.

The method may further comprise the step of adding solder balls or other electric contacts to the lower surface of first substrate.

The method may further comprise mounting a second module to the first module; the second module comprising a chip mounted on a third substrate. In this way a multichip package (e.g. a PoP) may be formed.

Preferably the third substrate of a the second module has first side with chip mounted to it and an opposite second side with electrical contacts which placed in contact with an exposed surface of the at least one second electrical contact of the first module.

### BRIEF DESCRIPTION OF THE DRAWINGS

Preferred embodiments of the present invention will now be described, by way of example only, with reference to the accompanying drawings in which:—

FIG. 1 is a prior art PoP which has already been described;

FIG. 2 shows a module for use in a multichip package, according to the present invention;

FIG. 3 shows another embodiment of a module for use in a multichip package;

FIG. 4 shows another embodiment of a module for use in a multichip package;

FIG. 5 shows another embodiment of a module for use in a multichip package;

FIG. 6 is a plan view of the second substrate;

FIG. 7 is a plan view of another embodiment of the second substrate;

FIG. 8 is a plan view of another embodiment of the second substrate;

FIG. 9 is a plan view of another embodiment of the second substrate;

FIG. 10 is a plan view of another embodiment of the second substrate;

FIG. 11 is a plan view of another embodiment of the second substrate;

FIG. 12 is a schematic view of a PoP assembly comprising first and second modules, according to the present invention;

FIG. 13 is a detailed illustration of the second substrate and surrounding components, including vias extending through the second substrate;

FIG. 14 (a) shows a pair of metal pillars used as electrical connectors between two substrates;

FIG. 14 (b) shows a pair of solder balls used as electrical connectors between two substrates;

FIG. 15 shows an alternative multi-layer construction of the second substrate; and

FIG. 16 shows steps in the assembly of a PoP according to the present invention.

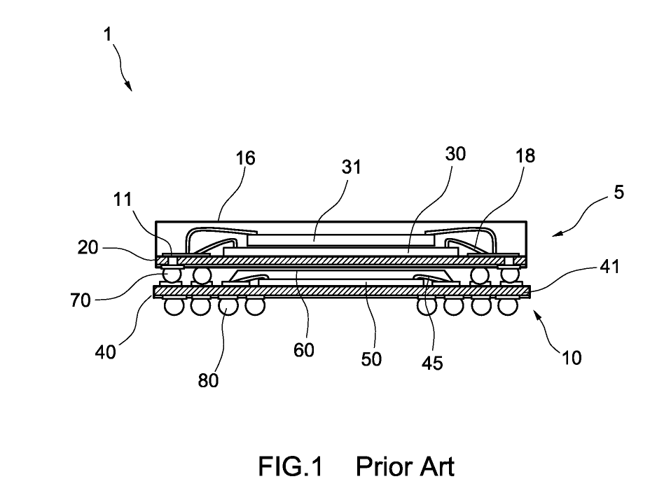

### DETAILED DESCRIPTION

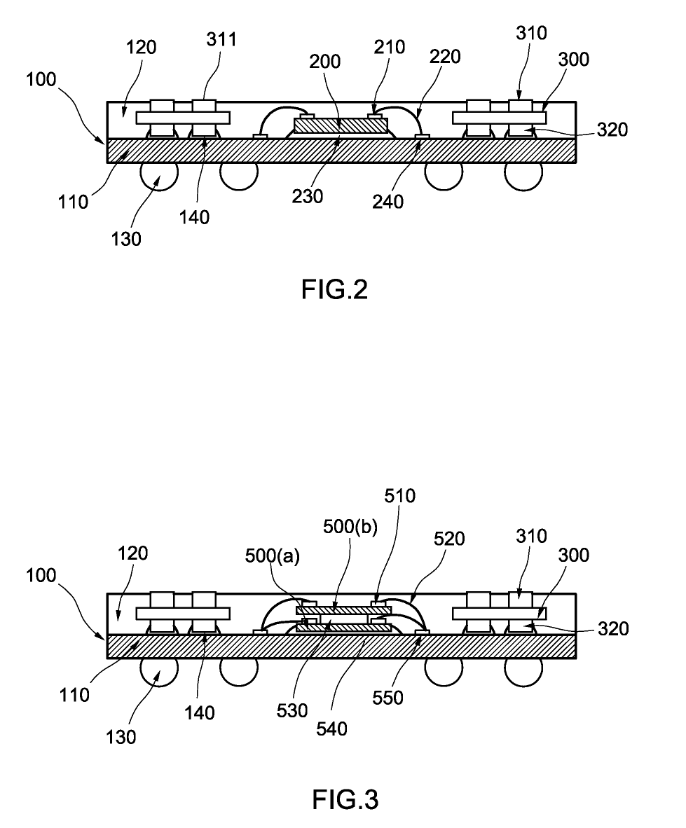

FIG. 2 shows a module 100 for use in a multichip package. In particular a module for use in the lower part of a PoP assembly. It comprises a first substrate 110 which maybe a PCB, preferably a BT core substrate. A (bismaleimide triazine) core substrate, is a substrate comprising a BT core layer with a metal layer on either side. BT has the advantage that it is a polymide with higher thermal stability, better chemical resistance and mechanical properties compared to the expoxy resin used in same other types of PCB. Solder balls 130 are provided on the lower side of the first substrate 110 to enable the module 100 to be mounted to an external apparatus, such as a motherboard. A chip 200, which may be a memory chip or a processor, is mounted to the first substrate 100. It may be mounted by any appropriate method, for example die attachment with wire bonding, flip chip etc. Wires 220 connect a bonding pad 210 on top of the chip 200 with a bonding pad 240 on the upper side of the first substrate 110.

A second substrate 300 is mounted to the first substrate 110. The second substrate has an opening therein for accommodating the chip 200. The second substrate 300 has a plurality of first connectors 320 for connecting the substrate electrically with the first substrate 110. The first connectors are provided on a first (underside) of the second substrate. A plurality of second connectors 310 are provided on the second (upper surface) of the second substrate 300. The first and second connectors preferably take the form of metal pillars, for example copper pillars. The first connectors may be electrically connected to the electrical contacts of the first substrate 110 by solder bonding or intermetallic bonding) 140. The assembly is overmolded with a molding material 120. The molding material covers the chip 200, the upper surface of the first substrate 110 and the second substrate 300. This overmolding helps to provide solidity and stability to the assembly and minimizes the occurrence of warping. Upper ends 311 of the second connectors 310 are exposed and are level with or extend above the upper surface of the overmold. The upper ends 311 may make contact with an external module. For example an upper PoP module may be mounted on top of the first module 110 and make electrical contact via the second connectors 311.

FIG. 3 shows another embodiment of the first module, similar to FIG. 2. Like reference numerals are used to describe like parts and will not be described again. This embodiment has two chips 500(a) and 500(b) stacked one on top of the other. The first chip 500(a) is mounted to the first substrate 110 by any suitable means. The second chip 500(b) is mounted on top of the first chip 500(a) and spaced apart from the first chip by a spacer 530. Wires 520 connect bonding pads on the chips 500(a), 500(b) to bonding pads on the first substrate 110. The molding material 120 covers both the first and second chips. The first and second chips may be of the same type (e.g. two processor chips), or may be of different types (e.g. one memory chip and one processor chip).

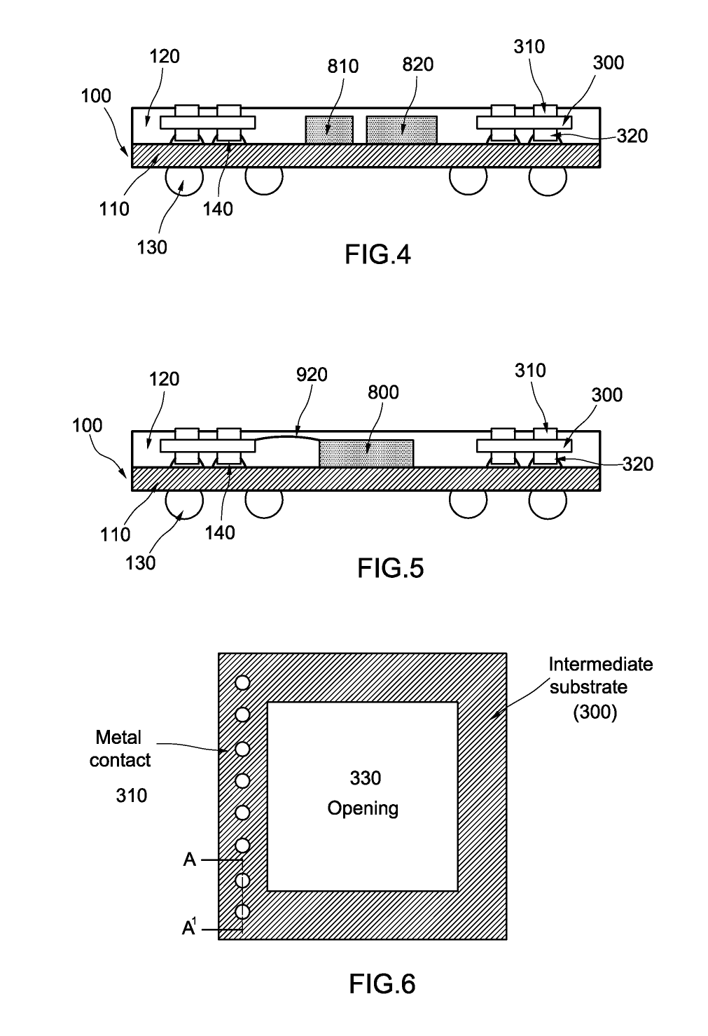

FIG. 4 is a third embodiment similar to the first two embodiments. It has two chips 810 and 820 mounted side by side on the first substrate 110. The overmolding material covers both the first and second chips 810, 820.

FIG. 5 shows a fourth embodiment similar to the first embodiment. The chip 800 is mounted on the first substrate 110. A wire 920 connects the chip 800 and the second substrate 300. The molding material covers the chip 800 and the first and second substrates 110, 300.

FIG. 6 is a plan view from above of the second substrate 300. The second substrate is also called the intermediate substrate as in the PoP assembly it is intermediate the first (main) substrate of the first module and the substrate of the second module. The second substrate 300 has a plurality of second connectors 310 (e.g. metal pillars) and an opening 330. There is a plurality of first connectors (not shown) in the corresponding location on the other side of the substrate. In this embodiment the second substrate 300 has a square or rectangular shape, the second connectors are arranged along one side of the second substrate and the opening is also square or rectangular in shape and in the centre. However, it is possible to have the second connectors at any location on the top surface of the second substrate. Furthermore, the second substrate may be any suitable shape and may have any shape or location of opening suitable for accommodating a chip mounted on the first substrate.

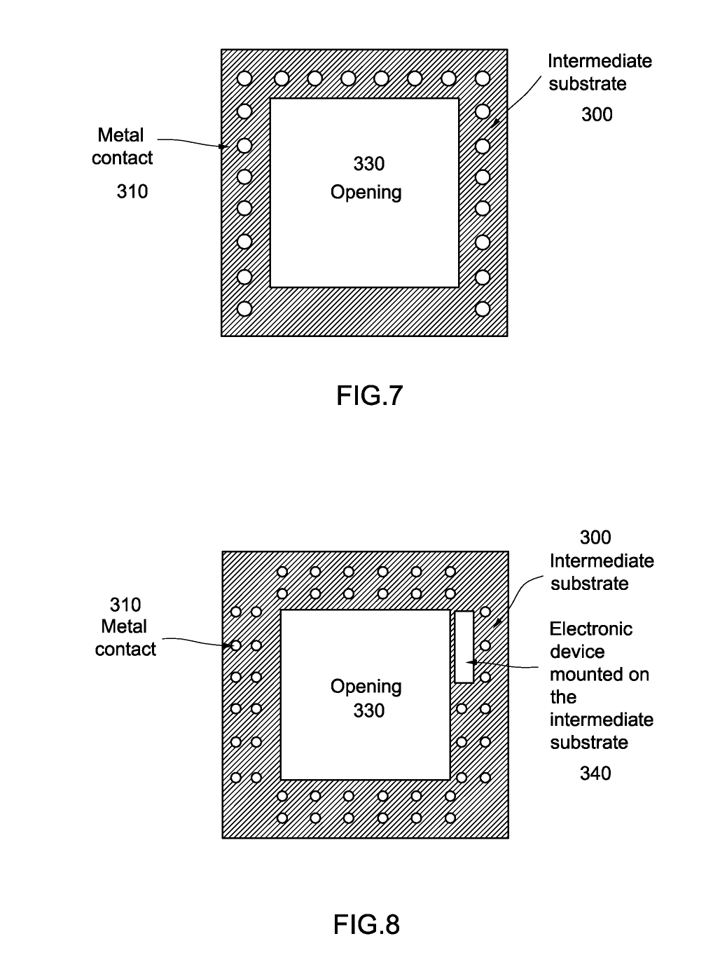

FIG. 7 is a plan view of a different arrangement for the second substrate 300. In this arrangement the second substrate has a line of second connectors 310 on three of its sides. First connectors (not shown) are provided in corresponding locations on the other side.

FIG. 8 is a plan view of another arrangement. A double row of second connectors 310 is provided on each side of the rectangular second substrate 300, surrounding the opening 330. First connectors are provided at corresponding locations on the other side. Further, there is an electronic device 340 mounted on top of the second substrate on the same side as the second connectors. The electronic device 340 could be, for example, a capacitor, resistor or active component.

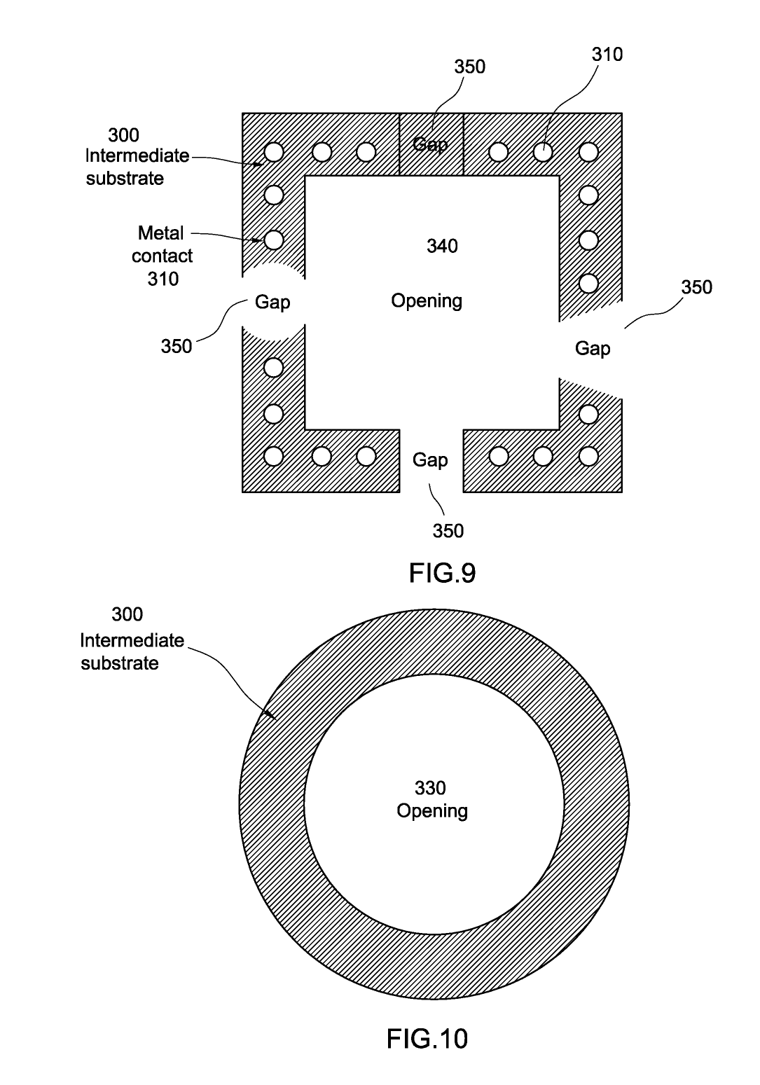

FIG. 9 shows yet another arrangement in which the second substrate 300 is rectangular and has a rectangular opening 340 in the middle. Second connectors 310 are provided in a line one each side and corresponding first connectors (not shown) are provided on the opposite face of the substrate. Each side has a gap 350. The gaps 350 are of different shapes and join the central opening 340.

FIG. 10 is an alternative arrangement in which the second substrate 300 is circular in shape and has a circular opening 330. First and second connectors (not shown) are provided on each side of the substrate.

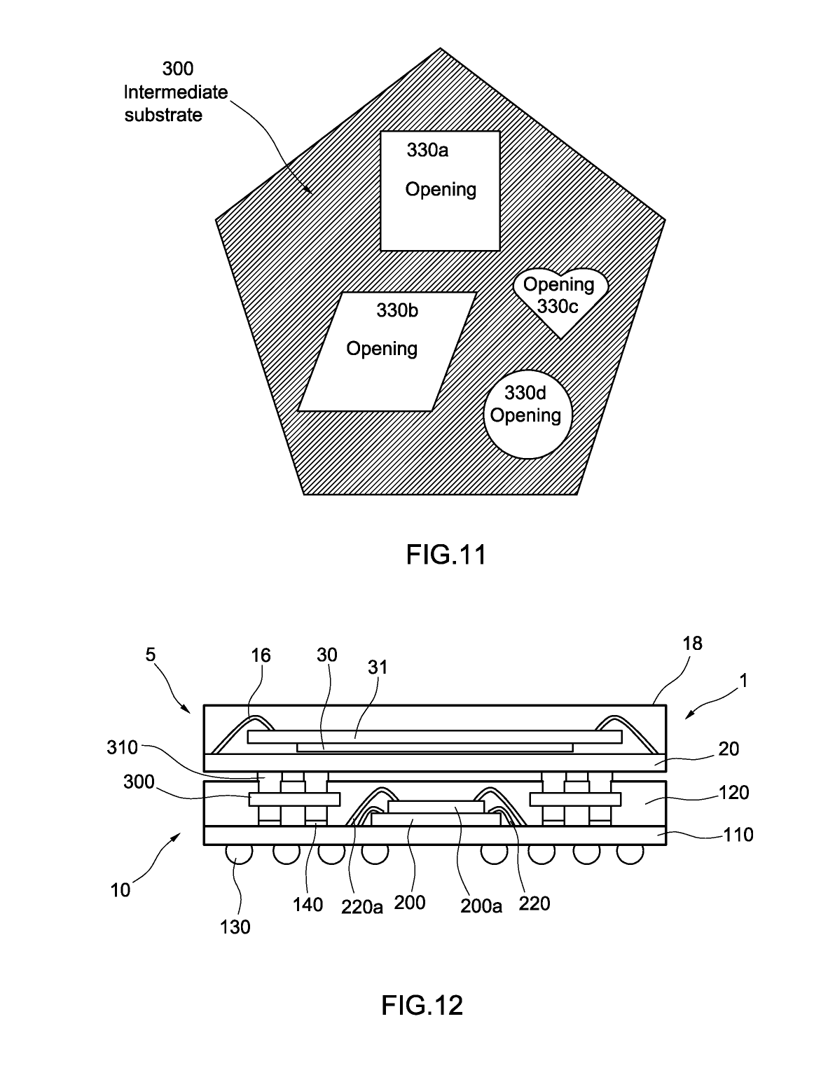

FIG. 11 is a further arrangement in which the second substrate 330 has a plurality of openings 330a, 330b, 330c and 330d of different shapes. Each may accommodate a different chip mounted on a substrate below. First and second connectors (not shown) are provided on the opposite sides of the substrate as discussed in the previous embodiments.

FIG. 12 is a schematic diagram of a PoP assembly 1 comprising a second module 5 mounted on a first module 10. The first module 5 is a module of the type described above, e.g. with reference to FIG. 2. It forms a lower module of the PoP assembly. In this example, it has two chips 200, 200a stacked one on top of the other and connected to a first substrate 110 by wires 220 and 220a respectively. Both chips are processors. Other embodiments could have a different number or type of chips and different method of connecting the chips to the substrate 110.

The upper module 5 comprises a pair of chips 30, 31 mounted to a first (upper) side of a third substrate 20. The third substrate may be a PCB, preferably a BT core substrate. The chips 30, 31 are electrically connected to the third substrate 20 by wires 16 or any other suitable means. Preferably the chips 30 and 31 are memory chips. The second module 5 is overmolded with a molding material 18 which covers the chips 30, 31 and the third substrate 20. The second (lower) side of the third substrate 20 is mounted to the first module 10. Specifically the third substrate is mounted directly to the second connectors 310 of the first module 5. Upper ends of the second connectors 310 connect with a conducting electrical contacts (not shown) of the second (lower) side of the third substrate 20 in order to allow communication of electrical signals between the two modules. While FIG. 12 shows a gap between the first and second modules, in other embodiments the overmold 120 of the first module may extend flush with the upper ends of the second connectors and the third substrate 20 of the second module 5 may rest on the overmold 120 of the first module. That is the third substrate 20 may be in direct contact with the overmold 120. In this embodiment there are no intervening PCBs or other electric circuits or insulators between the overmold 120 and second connectors 310 and the third substrate 20 of the second module 5. In this embodiment the two chips 31, 30 are memory chips, but in other embodiments they may be different types of chips (e.g. processors).

The first module 1 will now be described in more detail. It comprises a first substrate 110 which may be a PCB, preferably a BT core substrate. Solder balls 130 are provided on the lower side of the first substrate 110 to enable the module 100 to be mounted to an external apparatus, such as a motherboard. A pair of chips 200, 200a may be memory chips or a processor, are mounted to the first substrate 110. They may be mounted by any appropriate method, for example wire bonding, die attachment etc. Wires 220, 220a connect a bonding pad on top of the chip 200 with a bonding pad on the upper side of the first substrate 110.

A second substrate 300 is mounted to the first substrate 110. The second substrate has an opening therein for accommodating the chips 200, 200a. The second substrate 300 has a plurality of first connectors 320 for connecting the substrate electrically with the first substrate 110. The first connectors are provided on a first (underside) of the second substrate. A plurality of second connectors 310 are provided on the second (upper surface) of the second substrate 300. The first and second connectors preferably take the form of metal pillars, for example copper pillars. The first connectors may be electrically connected to the electrical contacts of the first substrate 110 by solder bonding 140. The first module 10 is overmolded with a molding material 120. The molding material covers the chips 200, 200a, the upper surface of the first substrate 110 and the second substrate 300. This overmolding helps to provide solidity and stability to the assembly and minimizes the occurrence of warping. Upper ends 311 of the second connectors 310 are exposed above the overmold 120. The upper ends 311 make contact with electrical contacts of the second module 5.

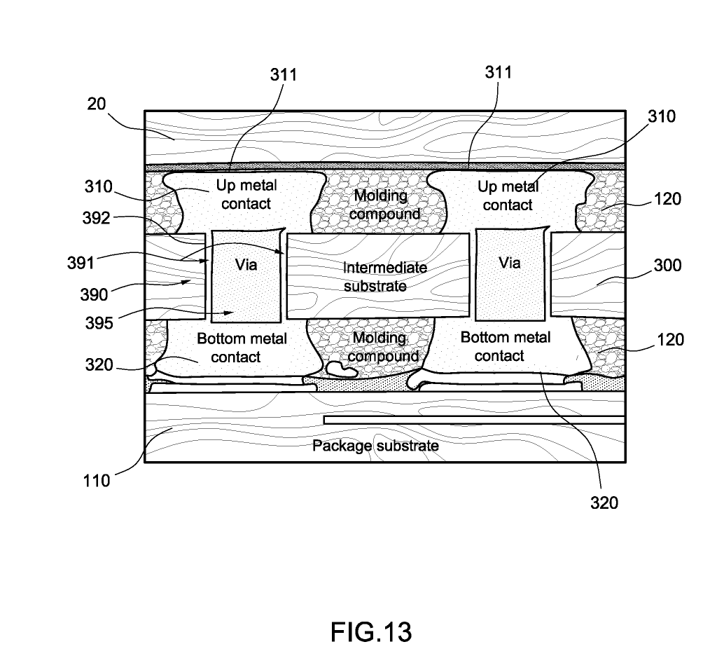

FIG. 13 shows the second substrate and surrounding components in more detail. In particular, it illustrates the vias 390 extending through the second substrate 300. First metal connectors 320 are provided on a second (lower) side of the second substrate 300. These are surrounded by the molding compound 120 and mounted to the first substrate 110. Second metal connectors 320 are provided on the first (upper) side of the second substrate. They are surrounded by the molding compound 120 and have exposed upper ends 311. The second metal connectors 310 are aligned with corresponding second metal connectors 310 on the opposite side of the substrate 300.

Vias 390 electrically connect each second metal connector 310 with a corresponding first metal connector 320. The vias 390 extend through the second substrate 300. The via has first 391 and second 392 side walls. These side walls 391, 392 may be part of the same (e.g. circular) side wall or may be separate side walls. The via 390 further comprises a core 395 between the side walls and extending between the first and second metal connectors 320, 310.

In the illustrated embodiment shown in FIG. 13 the side walls 391, 392 are electrically conductive (e.g. made of metal) and put the first and second metal connectors 320, 310 in electrical contact with each other. The core 395 of the via is an insulator. In alternative embodiments the core could instead by a conductive material (e.g. metal) or even a void. In still further embodiments the side walls could be an insulator and the core could be made of conductive material (e.g. metal).

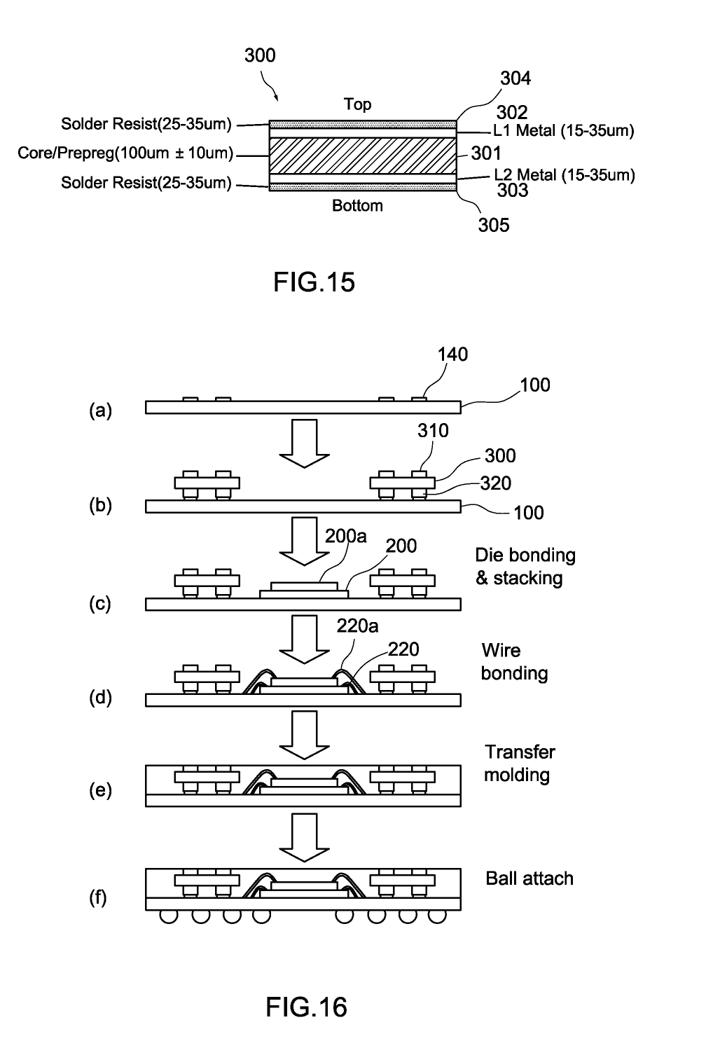

The second substrate 300 in the FIG. 13 embodiment is a simple insulator, e.g. polymer. However, in other embodiments it may be a PCB or it may comprise a plurality of layers. An example is shown in FIG. 15 where the second substrate 300 comprises a core/prepreg insulating layer 301, a metal layer 302, 303 on either side of the core layer and an insulating solder resist layer 304, 305 on either side of the metal layers.

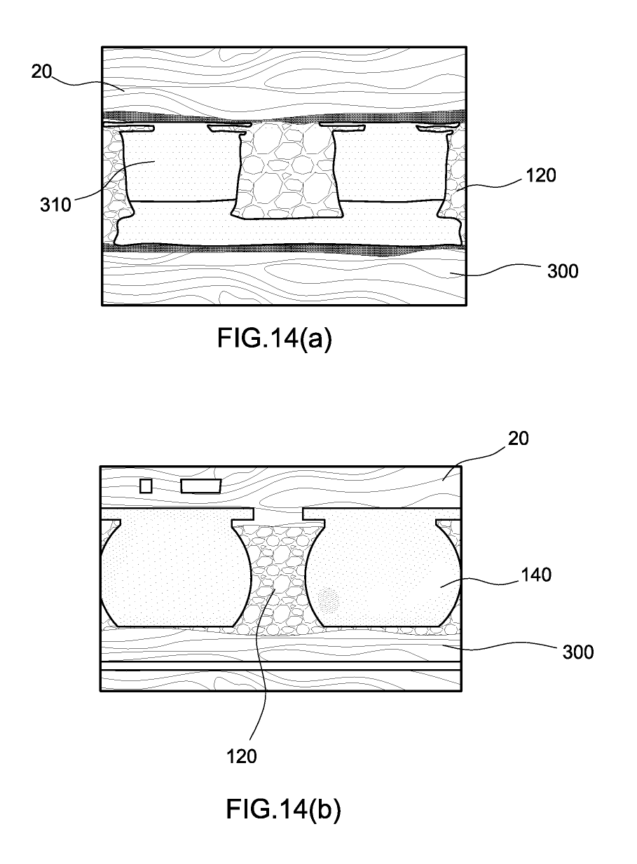

FIG. 14 (a) illustrates a pair of second connectors 310. They have the same structure as the first connectors 320. They are formed of metal pillars, preferably copper pillars. It can be seen that the pillars have fine pitch and a well defined shape. By way of contrast FIG. 14 (b) shows an arrangement with a pair of solder balls 140 between a substrate 20 and a substrate 300. It can be seen that the solder balls have a less fine pitch and less well defined shape than the metal pillars. Furthermore, at typical processing temperatures (e.g. around 260 degrees Celsius) the solder balls will melt and collapse down, while the metal (e.g. copper) pillars will remain solid and well defined. As a result, for a given stand off height, metal pillars provide a superior solution to solder balls for connecting the upper and lower surfaces of the second substrate to respective other substrates. The metal pillars allow finer pitch and thus denser electrical connections. A small amount of solder or bonding pads may used to connect the metal pillars to the respective other substrates.

A method of manufacturing the first module 10 will now be described with reference to FIG. 16.

In a first step, shown in FIG. 16 (a), bonding pads 140 are added to a first (upper) surface of a first substrate 300 at a location having electrical bonding pads or other electrical contacts. The first substrate 100 is preferably a PCB.

In a second step, shown in FIG. 16 (b), a second substrate 300 having second electrical connectors 310 on a first (upper) side thereof and first electrical connectors 320 on a second (lower) side thereof, is mounted to the first substrate 100. Specifically the first electrical connectors 320 are mounted to the bonding pads 140. The second substrate 300 has one or more openings therein.

In a third step, shown in FIG. 16 (c), one or more chips 200, 200a are mounted to the first substrate via the space provided by the opening in the second substrate.

In a fourth step, shown in FIG. 16 (d), the one or more chips 200, 200a are electrically connected to the first substrate 100. Specifically one or more wires 220, 220a are used to connect the chips to bonding pads on the first (upper) side of the first substrate 100. In other embodiments different methods may be used to electrically connect the chips to the first substrate, or the electrical connection may be intrinsic to the mounting thus rendering a separate connection step unnecessary.

In a fifth step, shown in FIG. 16 (e), the assembly is overmolded. Specifically a molding material is added to cover the first substrate and the second substrate and the chips, but leave exposed a surface of the second electrical connectors 310. Alternatively, the second electrical connectors may extend above the surface of the molding material; or the molding material may cover the upper ends of the second electrical connectors and later have a portion removed or scrapped off to expose the upper ends of the second electrical connectors. The molding material may be any suitable material, for example, an epoxy molding compound, a thermosetting polymer (preferably with particle filler, or a plastic material etc.

In a sixth step, shown in FIG. 16 (f), solder balls or other electric contacts 140 are added to a second (lower) surface of first substrate 110. Specifically the solder balls 140 are added to locations having conductive contacts on the second (lower) surface of the first substrate 110.

A second module may then be mounted to the first module shown in FIG. 16 (f) to form a PoP assembly. The second module may be a module 5 as shown in FIG. 12 and described above; it comprises a chip 30 mounted on a third substrate 20. The chip 30 is mounted on the first (upper) side of the third substrate, while electrical contacts (e.g. bonding pads or lands) present on the second (lower) side of the third substrate are placed in contact with the exposed ends of the second electrical connectors 310 of the first module 10.

While preferred embodiments of the present invention have been described above, they should not be taken to limit the scope of the invention, which is defined in the appended claims.

Having described the invention, the following is claimed:

1. A module for use in a multi-package assembly comprising:
a first substrate and at least one chip mounted on the first substrate;
a second substrate mounted to the first substrate and having an opening in therein; said opening being aligned with said at least one chip on the first substrate;
the second substrate being overmolded;
the first substrate being electrically connected to the second substrate by at least one first electrical connector; and
at least one second electrical connector extending from the second substrate through the overmold and having an exposed end for electrical connection to an external module.

2. The module of claim 1 wherein the first and second electrical connectors are metal pillars.

3. The module of claim 1 wherein the second substrate has only a single layer.

4. The module of claim 1 wherein the second substrate has plural layers

5. The module of claim 3 wherein the second substrate comprises a core insulator layer and conducting layers on either side of the core layer.

6. The module of claim 4 further comprising insulating layers outward of the conducting layers.

7. The module of claim 1 wherein the second substrate has a via extending through said second substrate, said via electrically connecting said at least one first electrical connector with said at least one second electrical connector.

8. The module of claim 7 wherein said via is a separate piece from said at least one first and at least one second electrical connectors.

9. The module of claim 7 wherein the via comprises first and second electrically conductive side walls; said first and second side walls being electrically connected to each other by said first electrical connector and said second electrical connector.

10. The module of claim 9 wherein the via has an insulating core between the side walls.

11. The module of claim 7 wherein the via comprises first and second insulating side walls and a conductive core for electrically connecting said first electrical connector and said second electrical connector.

12. The module of claim 1 wherein said at least one first electrical connector and said at least one second electrical connector are aligned with each other.

13. A multi-package assembly comprising the module of claim 1 as the first module and a second module comprising a chip mounted on a third substrate.

14. The assembly of claim 13 wherein the third substrate is mounted to and in direct contact with said overmold of the first module.

15. The assembly of claim 13 wherein the at least one second electrical connector is in contact with a conducting contact of the third substrate.

16. The assembly of claim 13 wherein the chip of the second module is mounted to a first side of the third substrate and a second side of the third substrate is mounted to the overmold of the first module.

17. The assembly of claim 13 wherein the chip of the first module is a processor and the chip of the second module is a memory chip.

18. A method of manufacturing a first module for use in a multi-package assembly comprising providing a second substrate having at least one first electrical connector on a first side thereof and at least one second electrical connector on a second side thereof and one or more openings; mounting the second substrate to a first substrate; mounting one or more chips on the first substrate via the space provided by the opening in the second substrate; adding molding material to cover the first substrate and the second substrate and the one or more chips and wherein a surface of the at least one second electrical contact is left exposed.

19. The method of claim 18 wherein the at least one second electrical contact is covered by said molding material and a portion of the molding material is later removed to expose a surface of the at least one second electrical contact.

20. The method of claim 18 further comprising the step of adding solder balls or other electric contacts to the lower surface of first substrate.

21. The method of claim 18 further comprising mounting a second module to the first module; the second module comprising a chip mounted on a third substrate.

22. The method of claim 21 wherein the third substrate has first side with a chip mounted to it and an opposite second side with electrical contacts which are placed in contact with an exposed surface of the at least one second electrical connector of the first module.
